(19) United States
(12) Patent Application Publication
(10) Pub. No.: US 2004/0175943 A1
(43) Pub. Date: Sep. 9, 2004

(54) System and method of pattern detection for semiconductor wafer map data

(76) Inventor: Peter Waksman, Concord, MA (US)

Correspondence Address: Peter Waksman, 54 Minot Rd., Concord, MA, 01742, US

(21) Appl. No.: 10/751,602

(22) Filed: Jan. 5, 2004

Related U.S. Application Data
(60) Provisional application No. 60/452,468, filed on Mar. 6, 2003.

(51) Int. Cl. H01L 21/00; H01L 21/302; H01L 21/461

(52) U.S. Cl. 438/689

(57) ABSTRACT

A system and method is described for detecting the presence of spatial non-randomness in semiconductor wafer map data comprised of a computer or embedded processor with the ability to interpret and extract the two-dimensional position of events defined in the data; a set of sub-regions of the wafer; a program for calculating multiple chi-squared values, each testing the null hypothesis that events counted inside a sub-region are random and in proportion to the area of the sub-region; a method for sending the result values to a destination, either inserted into the original data or as a separate result record; and a mechanism for testing the results to see if they satisfy an alarm condition and generating an appropriate response.

### BACKGROUND OF INVENTION

Applicant claim priority of Provisional Application No. 60/452,468 filed Mar. 06, 2003.

1. Field of the Invention

This invention relates to semiconductor wafer maps, corresponding to data collected over the surface of a semiconductor wafer. Typical examples of data include defect data collected by optical inspection equipment, or electrical probe data collected at test points on the wafer surface. Wafer maps display the data as a two dimensional picture. This invention discloses a means for measuring the spatial non-randomness of the underlying mapped data; and for testing the non-randomness to determine if an alarm condition is satisfied.

2. Prior Art

During the manufacture of semiconductor wafers, data is collected and displayed as a two dimensional wafer map. Examples of data include defect data from optical inspection equipment and electrical probe data collected at the end of the manufacturing process to determine the electrical characteristics of individual semiconductor chips. The value of this data for tracking wafer and chip quality is well known. Throughout this disclosure, defect data is used as a standard example.

Manufacturers expend time and manpower evaluating wafer maps visually and applying quality benchmarks to determine if the manufacturing process needs to be adjusted. For example with defect data, a standard practice is to track defect count as a basic measure of quality. When the defect count exceeds a specified threshold, then the defect wafer map is examined visually. Depending on the results, a judgment may be made to scrap or re-work a wafer and, in any case, to diagnose the source of the defects and make appropriate adjustments to the processing equipment and the processing environment.

Prior art includes systems which recognize patterns in the wafer map data [Tobin, K. W., Jr., Gleason, S. S., Karnowsi, T. P., and Sari-Sarraf H., Automated Defect Signature Analysis for Semiconductor Manufacturing Process Improvement, Filed Jan. 7, 1997]. Such recognition systems fail to provide good alarm mechanisms because (a) these systems use discrete pattern identifiers which do not properly describe the continuum of cases; and (b) new patterns frequently arise which are not recognized. These systems are also limited because they require input from the user. Accordingly, recognition systems do not provide a robust detection and alarm mechanism.

Prior art also includes means for triggering an alarm based on defect count and on statistical process control rules, such as the “Western Electric” rule, which define alarm conditions based on the sequence and trend of defect counts over successive wafers. Such rules are used throughout the semiconductor industry. The limitations of such systems and methods are known to most practitioners, namely that defect count is not predictive of defect causality. Sometimes low defect count wafer maps are ignored when they should be examined, or high defect counts, exceeding a predetermined threshold, only occur after the physical cause of the defects has been operating for some time, spoiling many wafers before the alarm condition is triggered. Also there can be high defect count wafers with no significant information about causality in which case an alarm condition occurs but no action will be taken. Thus low defect count conditions may be missed even though they are significant, and high defect count conditions may be examined and found to be of no significance, or the examination may come too late. These inadequacies lead to costly errors: either high cost of manpower examining wafers of no interest or the even higher cost of failing to stop a defective process until many wafers have been spoiled.

Thus neither pattern recognition systems nor SPC rule-based alarm systems with event counting address the fundamental problem of determining degree of causality implied by spatial non-randomness of the data.

### OBJECT OF THE INVENTION

From the point of view described above, the object of the present invention is to provide a quantitative measurement of spatial non-randomness of data displayed as a wafer map, and to utilize this measurement as the basis of an Alarm and pre-Alarm mechanism in day-to-day monitoring of semiconductor wafer data.

With an accurate system and method for measuring non-randomness in defect data, the responsible engineer can take immediate action to isolate and repair the cause of a non-randomness, potentially saving hundreds of thousands of dollars in damaged product, by reacting quickly and in a timely manner.

### SUMMARY OF THE INVENTION

This invention is the result of applying a very simple principle:

If events in a region are spatially random then the number of events occurring in a sub-region is proportional to the area of the sub-region.

This principle is applied to the whole wafer map as a region, with sub-regions defined by half-disks, concentric bands, and bands across the wafer. The ‘events’ may be defects, or defects of a particular type, or chips with specific electrical characteristics. The chi squared formula from traditional statistics provides a way to measure non-randomness by testing the ‘null’ hypothesis that the events are random.

For example if a wafer map is divided in half along a diameter line, and defects on the wafer are random, then approximately ½ the defects are expected on each side of the line. Or if a concentric circular band around the wafer center has area p, where the area of a whole wafer is 1 and p is a number between 0 and 1, then we expect pN defects from a total of N defects on the wafer. (See FIG. 2).

### DESCRIPTION OF FIGURES

FIG. 1 shows a schematic for a pattern detection system and method, including a data source; a computer equipped with a program for interpreting events in the data for each wafer and making the chi-squared calculations; and sending results to a destination. Source and destination are represented by folder outlines and the “{χ²}” represents the collection of chi-squared values. Results may be sent to the destination in the form of a summary or may be inserted back into the data, which is then sent to the destination. The system and method also may be configured to raise an alarm when defined conditions on the chi-squared values are satisfied, such as exceeding a threshold.

FIG. 2 shows an event count inside the region, combined with the total number of events, using the chi squared formula and the subregion area to produce a measure of spatial non-randomness.

FIG. 3 shows the wafer map represented as a circular region with a set of standard subdivisions including: 6 lateral division along diameter line; five concentric radial divisions; and four axial divisions using bands across the wafer.

FIG. 4 shows a set of events, represented by an irregular gray domain, on a wafer, and the calculation of 6 lateral chi-squared values, one for each lateral subdivision; the calculation of 5 radial chi-squared values, one for each radial subdivision; and the calculation of 4 axial chi-squared values, one for each axial subdivision. The max of the lateral chi-squared is calculated, the max of the radial chi-squared is calculated, the max of the axial chi-squared values is calculated, also the max of all chi-squared is calculated

FIG. 5 shows other obvious sub-divisions of the wafer map area. Top row shows rectangular tiles, and angular sectors. Bottom row shows are regions around the wafer edge and specialized rectangular zones.

### DETAILED DESCRIPTION OF THE INVENTION (PREFERRED EMBODIMENT)

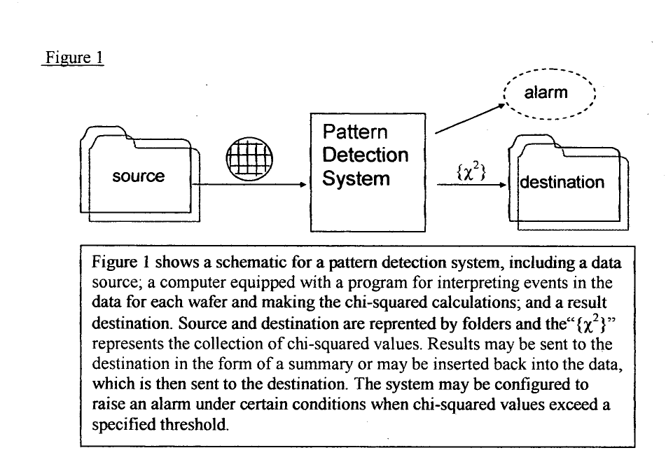

FIG. 1 shows a schematic for a pattern detection system implemented as a computer with a data source for input and a data destination for output. The computer may also generate alarms. Mechanisms for computer input/output and communication are well known. Also embedded computers inside dedicated equipment are well known. This document discloses a specific mechanism for calculating a measure of non-randomness in semiconductor wafer data.

Data, containing wafer map information, appears in many formats such as ascii files and binary data files. It is understood that the underlying two-dimensional data can be interpreted by the computer and that, although an implementation may be limited to certain data formats and communication methods, this invention includes all such implementations. It is the details of the calculation along with obvious variations which is the subject of this disclosure.

The calculation, which is central to this disclosure, is a chi-squared calculation for the ‘null hypothesis’ that the events on the wafer are random. An event may be thought of as a value associated to a position on the wafer. Wafer data usually contains information about many events on the wafer. We follow the principle that when there are many events on the wafer, if they are spatially random, then the number of events inside a sub-region should be proportional to the area of the sub-region.

Examples of events include (a) a defect is located at this position (true/false); (b) a defect of a particular type is located at this position (true/false); (c) one or more electrical parameters are measured at this position and they fall within pre-determined ranges (true/false). In all cases the event may be represented as a dot at the specified position on the display of the wafer, or as a color for a complete die. Such dots and outlines and means of displaying a wafer map are well know.

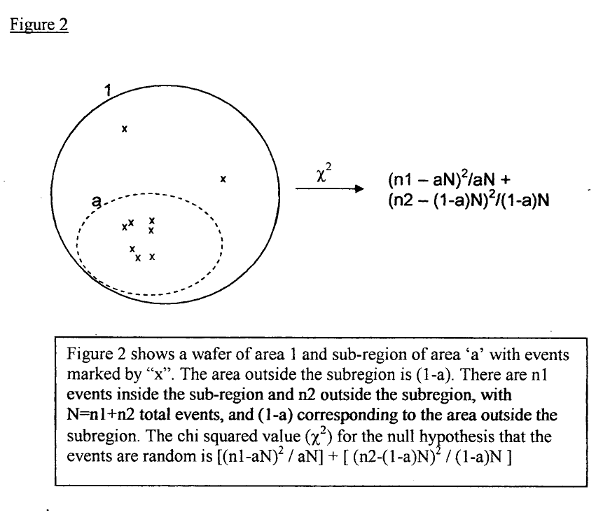

FIG. 2 shows a wafer map with one sub-region indicated by a dashed outline. The whole wafer is assigned an area of 1 and the sub-region has a corresponding area ‘a’ between 0 and 1. There are n1 events inside the region and n2 outside the region. So the total number of events is N=n1+n2. In this case the ‘null’ hypothesis that the event locations are random suggests that the number inside should be proportional to the area of the sub-region. [Probabilities calculated by area ratios are a subject of one branch of mathematics called “Geometric Probability”]. According to the null hypothesis that the events are random, the expected distribution is aN defects inside and (1−a)N defects outside. The actual distribution of events has n1 events inside and n2 outside, hence the chi-squared formula for the null hypothesis is

χ²=[(n1−aN)²/aN]+[(n2−(1−a)N)²/(1−a)N] (*)

It is well known that this number increases as the null hypothesis becomes increasingly untenable. Hence the larger the value of this number, the more non-random is the location of the events.

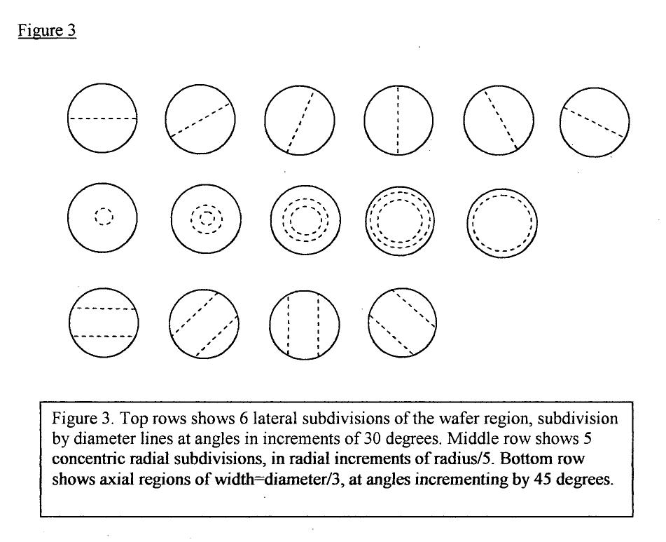

The formula (*) gives a measure of non-randomness with respect to the sub-region used for the calculations. To apply this to many different choices of sub-region we disclose a standard set of sub-regions in FIG. 3. These include lateral sub-regions formed by dividing the wafer area in half along diameters at various angles. They also include concentric radial regions inside, outside, or between concentric circles. They also include axial regions which extend on either side of a diameter line at various angles.

A chi-squared value is calculated for each sub-region. Each division of the wafer map (illustrated in FIG. 3) creates a sub-region and its compliment (everything outside the sub-region). Since the formula (*) is symmetric, the calculation only needs to be done once for a sub-region and need not be calculated for the compliment. Hence for the lateral sub-regions, one side of the division line is used for the calculation but the other side does not need to be used. Similarly for radial and axial regions: once the calculation is done for the sub-region (between dashed lines in FIG. 3), it does not need to be calculated for the complimentary sub-regions outside these lines.

There are certain advantages to the standard set of sub-divisions illustrated in FIG. 3. One advantage is that the lateral, radial and axial sub-divisions are somewhat independent of each other and capture different aspects of the wafer data. Another advantage is that this is a manageable set of sub-divisions, easily calculated. However other sub-divisions are possible and may even be recommended in particular cases. For example a specific application might wish to measure non-randomness with respect to an irregular “L” shaped sub-region located over a sensitive area of the wafer. The application of formula (*) is the same and this should be understood as a variation of this invention which will be obvious to anyone familiar with the idea and with reasonable expertise in semiconductor data management.

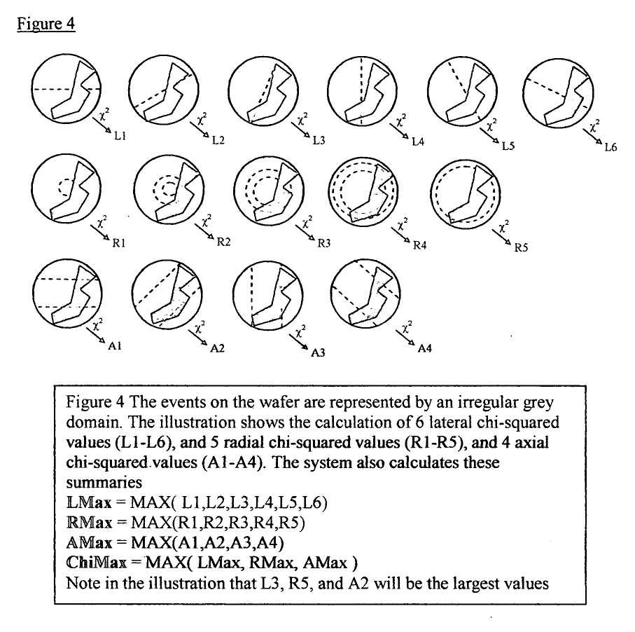

FIG. 4 shows the use of many different sub-regions, where a chi-squared calculation is done for each one. These values are grouped and maximized to provide a summary for that group. In FIG. 4, grouping the lateral, radial, and axial sub-regions respectively, we calculate “lateral chi-squared”, “radial chi-squared”, and “axial chi-squared”. Further the maximum over all sub-regions “chi max” is calculated. Any or all of these may be kept as results and used as the basis of an alarm. In particular the chi-squared are calculated for 6 lateral regions to give L1, L2, L3, L4, L5, and L6 and their maximum LMax. Also the chi-squared are calculated for the 5 radial regions to give R1, R2, R3, R4, R5 and their maximum RMax. Also the chi-squared are calculated for the 4 axial regions to give A1,A2, A2, A4, and their maximum AMax. Finally the maximum of the chi-squared over all sub-regions is found to give ChiMax.

These results may be used to determine an alarm condition. For example we might define alarm levels as follows:

ALARAM0: ChiMax>10

ALARAM1: ChiMax>35

ALARAM2: ChiMax>65

ALARAM3: ChiMax>150

ALARAM4: ChiMax>300

It is well known technique to write a computer program which will send an email or initiate an alarm, depending on when monitoring of data produces results which satisfy any of these ALARM conditions.

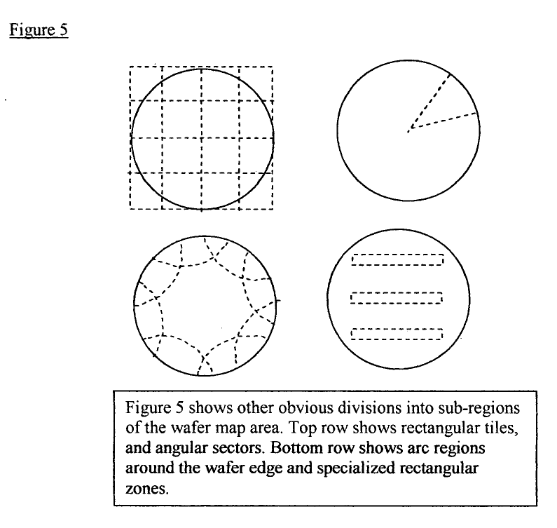

There are obvious extensions of this invention. For example the set of sub-regions could be replaced by some other set of subregions. There are many possibilities, including sets of rectangular sub-regions which tile the wafer, or sectors between radial lines at different angles, or semicircular sub-regions taken around the edge of the wafer, or specialized sub-rectangles of the wafer. Some of these obvious possibilities are illustrated in FIG. 5.

Other variations on the basic idea are achieved with different algebraic combinations and operations on the chi-squared. These include the obvious averaging or maximizing of some but not all of the chi-squared, or adding other sub-regions to the lateral, radial, and axial groups. All these take advantage of the basic idea of sub-regions with area and chi-squared calculations based on the relative number of events in a sample of known number of events.

Also there are reasonable pre-processing steps that could be applied to the data. One interesting pre-processing step is scratch removal, where individual defects are classified as belonging to a scratch and those defects are removed from the chi-squared calculations (they are just not counted). This provides a measure of non-randomness for the data excluding scratches. Such a measure may be valuable when a scratch is superposed on some other processing problem and it is worth having separate alarms for both.

A further example of pre-process is taking the logical union, or “composite”, of several different sets of data, to form a composite wafer. Detecting non-randomness in the composite wafer map is another obvious application of the basic idea of this disclosure and is included in it.

Finally there are many other semiconductor wafer metrics. These include defect count, presence of a cluster, and a variety of attributes too numerous to list. Alarm conditions which include the chi-squared numbers also take advantage of the basic idea of this invention. Thus a typical condition might be:

ALARM: ChiMax>35 AND DefectCount>10

Conditions and alarm systems built around them, with the obvious computing infrastructure, and containing the use of sub-regional chi-squared values are included in the understanding of this disclosure.

It should also be understood that not all wafers manufactured by photo-lithographic processes are circular, some are rectangular and some are not called “semiconductors”. However the word “wafer” as understood here applies to all such items of photo-lithographic manufacture.

Another variation on the idea of this invention applies the chi-squared calculation to single dies or reticle steps on the wafer. In this variation a “master” is used and sub-regions of the die or reticle are defined relative to position in this master. Each allowed position of the master within the whole wafer gives another set of chi-squared values. Individual values or collective properties of all values as the master is stepped across the wafer provide another natural mechanism for defining alarm conditions.

What is claimed is as follows:

1. A system and method for detecting and reporting the presence of non-randomness in wafer data comprising the steps of:
reading input wafer data from a source
calculating a chi-squared value for each of a collection of sub-regions, using sub-region relative area ‘a’, within a total region of area 1; and using event counts n1 inside the region and n2 outside the region and the formula (where N=n1+n2)
χ²=[(n1−aN)²/aN]+[(n2−(1−a)N)²/(1−a)N]
determining if these chi-squared values satisfy a defined alarm condition and generating an appropriate response
writing chi-squared results as output to a destination.

2. A system and method as described in claim 1 where the system is implemented as a stand alone computer connected to the data source and destination by a computer network.

3. A system and method as described in claim 1 where the system is implemented within an embedded processor inside equipment which also performs other dedicated tasks.

4. A system and method as described in claim 1 where the set of sub-regions is comprised of 6 lateral regions, 5 radial regions, and 4 axial regions. Where the lateral regions are defined by diameter lines at 6 different angles in increments of 30 degrees starting from the horizontal. Where the radial regions are defined between concentric circles of different radii in increments of radius/5. Where the axial regions are defined with width diameter/3 and centered on axes at 4 different angles in 45 degree increments starting from the horizontal.

5. A system and method as described in claim 1 where the alarm condition includes a test of the maximum chi-squared exceeding a designated threshold.

6. A system and method as described in claim 1 where the events are defect positions in defect data.

7. A system and method as described in claim 1 where the events are defined by electrical probe data on individual chips such that each chip is an event if its probed electrical values lie in designated numeric ranges.

8. A system and method as described in claim 1 where the events are pre-filtered to eliminate some of the events from the calculation.

9. A system and method as described in claim 7 where the chips with different probe characteristics are grouped to form the data used in the calculation.

10. A system and method as described in claim 1 where the system is applied more than once to provide separate chi-squared summaries and these different results are combined afterwards to provide an alarm condition.

11. A system and method as described in claim 1 where the sub-regions are rectangular tiles.

12. A system and method as described in claim 1 where the sub-regions are angular sectors.

13. A system and method as described in claim 1 where the sub-regions are user defined regions of the wafer, where the design matches a desired shape outline.

14. A system and method as described in claim 1 where the events are the logical union, or composite, data from several wafers.

15. A system and method as described in claim 1 where the data of a wafer is replaced with the data from a single reticle step on a wafer; and the sub-regions and areas are defined by reticle location rather than wafer location. The chi-squared calculation is done with events restricted to a single position of the reticle.
